(19) United States
(12) Patent Application Publication
(10) Pub. No.: US 2019/0276932 A1
(43) Pub. Date: Sep. 12, 2019

(54) FILM FORMING APPARATUS AND FILM FORMING METHOD

(71) Applicant: Shimadzu Corporation, Kyoto (JP)

(72) Inventors: Yuu TOKUTAKE, Hadano-shi (JP); Satoru OZAKI, Hadano-shi (JP); Naoki YOSHIOKA, Hadano-shi (JP); Suguru TANAKA, Hadano-shi (JP); Takaharu NISHIHARA, Hadano-shi (JP)

(21) Appl. No.: 15/915,293

(22) Filed: Mar. 8, 2018

(51) Int. Cl. C23C 16/44; C23C 16/513

(52) U.S. Cl. CPC C23C 16/4401; C23C 16/513

(57) ABSTRACT

A film forming apparatus includes a chamber configured to store a workpiece, an electrode to which power is supplied to form a film on the workpiece, the electrode being disposed in the chamber, and a temperature adjustment device. The temperature adjustment device adjusts a temperature of the electrode so that the temperature of the electrode is kept substantially constant in a film forming process for forming the film on the workpiece and in processes other than the film forming process during a series of film forming processes for forming the film on the workpiece to prevent separation of a film forming material deposited on the electrode from the electrode.

### BACKGROUND OF THE INVENTION

### Field of the Invention

The present invention relates to a film forming apparatus in which an electrode is disposed in a chamber and a film forming method.

### Description of the Related Art

As a film forming apparatus for forming a film on a workpiece as a processing object, a plasma chemical vapor deposition (CVD) apparatus and a sputtering apparatus are used. In these film forming apparatuses, a film forming material is deposited also on the inner wall surface of the chamber and the surface of the electrode disposed in the chamber during the film forming process. When these film forming materials are separated from the chamber and/or the electrode and adhered to a workpiece, there occur problems, such as, e.g., deterioration of the film quality of the thin film formed on the workpiece. For this reason, for example, countermeasures, such as, e.g., placing a deposition preventing plate covering the inner wall surface of the chamber, have been considered (Japanese Unexamined Patent Application Publication No. 2007-012907).

A temperature of an electrode arranged in a chamber generally rises during the film forming process by, e.g., being exposed to plasma in a chamber of a plasma CVD apparatus. As a result, the electrode expands. On the other hand, when exchanging workpieces, since the chamber is opened to the atmosphere, the temperature of the electrode is lowered due to heat release. As a result, the electrode contracts. As the electrode deforms due to the temperature changes, the film forming material separates from the electrode due to the difference in coefficient of thermal expansion between the electrode and the film forming material. As a result, there occur such problems that a film forming material adheres to the workpiece.

### SUMMARY OF THE INVENTION

According to one embodiment of the present invention, a film forming apparatus for forming a film on a workpiece, comprising: a chamber configured to store the workpiece; an electrode to which power is supplied to form a film on the workpiece, the electrode being disposed in the chamber; and a temperature adjustment device, wherein the temperature adjustment device is configured to adjust a temperature of the electrode so that the temperature of the electrode is kept substantially constant in a film forming process for forming the film on the workpiece and in processes other than the film forming process during a series of film forming processes for forming the film on the workpiece to prevent separation of a film forming material deposited on the electrode from the electrode.

According to another embodiment of the present invention, a film forming method including a series of film forming processes comprising: storing a workpiece as a film forming process object in a chamber; supplying predetermined power to an electrode disposed in the chamber to form a film on the workpiece; and exposing the chamber to the atmosphere after forming the film on the workpiece, wherein a temperature of the electrode is adjusted such that the temperature of the electrode is kept substantially constant in a film forming process for forming the film on the workpiece and in processes other than the film forming process to prevent separation of the film forming material deposited on the electrode.

### BRIEF DESCRIPTION OF THE DRAWINGS

FIG. 1 is a schematic diagram showing a configuration of a film forming apparatus according to a first embodiment of the present invention.

FIG. 2 is a flowchart for explaining a film forming method using the film forming apparatus according to the first embodiment of the present invention.

FIG. 3 is a schematic diagram showing a configuration of a film forming apparatus according to a second embodiment of the present invention.

FIG. 4 is a schematic diagram for explaining the operation of the film forming apparatus according to the second embodiment of the present invention.

FIG. 5 is a schematic diagram showing a configuration of a film forming apparatus according to another embodiment of the present invention.

### DETAILED DESCRIPTION OF THE INVENTION

Some embodiments of the present invention will be described with reference to the drawings. In the following description of the drawings, the same or similar reference numerals are allotted to the same or similar parts. However, it should be noted that the drawings are schematic. It should also be noted that the embodiments described below exemplify apparatuses and methods for embodying the technical idea of the present invention, and embodiments of the present invention do not specify the structure, arrangement, etc., of components described below. The embodiments of the present invention can be variously modified within the scope of claims.

### (First Embodiment)

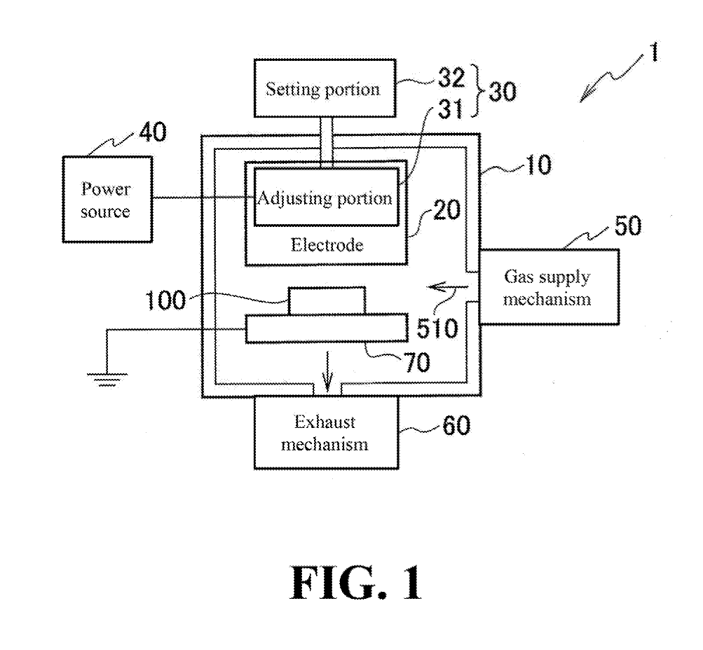

As shown in FIG. 1, the film forming apparatus 1 according to the first embodiment of the present invention is provided with a chamber 10 in which a workpiece 100 as a processing object is stored, an electrode 20 to which power is supplied to form a film on the workpiece 100, the electrode being arranged in the chamber 10, and a temperature adjustment device 30 for adjusting the temperature of the electrode 20.

The film forming apparatus 1 shown in FIG. 1 is a plasma CVD apparatus for forming a film on the workpiece 100 by a plasma CVD method, and is provided with a power source 40 for supplying power to the electrode 20, a gas supply mechanism 50, and an exhaust mechanism 60. The power source 40 is, for example, a high-frequency power source. The gas supply mechanism 50 supplies a material gas 510 for forming a thin film on the workpiece 100 to the inside of the chamber 10. The exhaust mechanism 60 discharges the gas in the chamber 10 to the outside. A gas pressure regulating valve (not shown) is provided in the exhaust mechanism 60, so that the pressure inside the chamber 10 is kept constant.

In the film forming apparatus 1, plasma of the material gas 510 is formed between the electrode 20 disposed in the chamber 10 so as to face the workpiece 100 and the workpiece holder 70 on which the workpiece 100 is to be mounted. For example, the electrode 20 is served as a cathode electrode and the workpiece holder 70 is served as an anode electrode. The workpiece 100 is exposed to the plasma generated inside the chamber 10, so that a film made of the material contained in the material gas 510 as a main component is deposited on the workpiece 100.

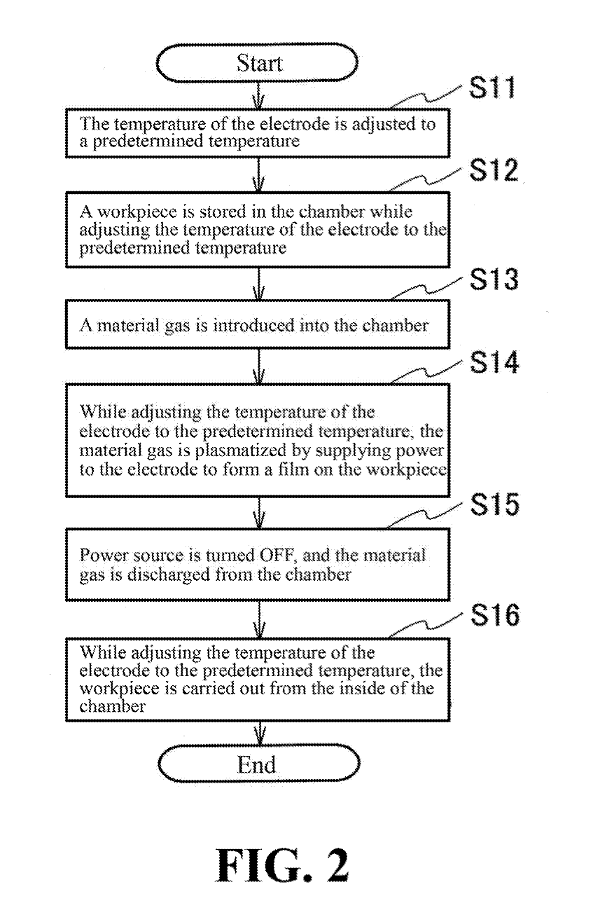

Hereinafter, an example of a method of forming a thin film by the film forming apparatus 1 will be described with reference to FIG. 2.

In Step S11, the temperature of the electrode 20 is adjusted to a predetermined temperature by the temperature adjustment device 30. Next, in Step S12, while adjusting the temperature of the electrode 20 to the predetermined temperature, the workpiece 100 as a film forming process object is stored in the chamber 10. Thereafter, the inside of the chamber 10 is vacuumed by the exhaust mechanism 60.

In Step S13, a material gas 510 is introduced into the chamber 10 by the gas supply mechanism 50. Next, the inside of the chamber 10 is depressurized by the exhaust mechanism 60 to adjust the material gas 510 in the chamber 10 to a predetermined gas pressure.

In Step S14 of the film forming process, the power source 40 is turned on to supply predetermined power to the electrode 20. With this, the material gas 510 in the chamber 10 is plasmatized. The excited species in the formed plasma react on the surface of the workpiece 100, so that a thin film is formed on the surface of the workpiece 100. Also in this film forming process, the temperature of the electrode 20 is adjusted by the temperature adjustment device 30. That is, the film formation of the workpiece 100 is performed while adjusting the temperature of the electrode 20 to the predetermined temperature.

After forming a film having a predetermined film thickness on the workpiece 100, the power source 40 is turned off in Step S15 to terminate the film forming process. Next, the material gas 510 is discharged from the chamber 10 by the exhaust mechanism 60. Thereafter, in Step S16, while adjusting the temperature of the electrode 20 to the predetermined temperature, the chamber 10 is opened to the atmosphere, and the workpiece 100 in which a film has already been formed thereon is carried out of the chamber 10.

A predetermined film is formed on the workpiece 100 by the above described series of the film forming processes. When the film forming apparatus 1 is continuously operated, returning to Step S11, an unprocessed new workpiece 100 is stored in the chamber 10.

The temperature adjustment device 30 adjusts the temperature of the electrode 20 so that the temperature of the electrode 20 is kept constant in the series of film forming processes described with reference to FIG. 2 to prevent separation of the film forming material deposited on the electrode 20 from the electrode 20. That is, in the film forming apparatus 1, the temperature of the electrode 20 is kept constant in the film forming process for forming a film on the workpiece 100 and in processes other than the film forming process. For example, the temperature of the electrode 20 is kept constant when the chamber 10 is opened to the atmosphere for exchanging workpieces 100 and when the film forming process is being performed. For this reason, deformations of the electrode 20 due to temperature fluctuations are suppressed. As a result, separation of the film-formed material from the electrode due to the difference in coefficient of thermal expansion between the electrode and the film-formed material is suppressed.

The temperature adjustment device 30 shown in FIG. 1 includes an adjusting portion 31 disposed on the electrode 20 and a setting portion 32 for setting the temperature of the adjusting portion 31. For example, as the adjusting portion 31, a circulation water passage through which heated water flows is formed inside the electrode 20. Then, heated water in which the temperature is adjusted by the setting portion 32 is supplied to the adjusting portion 31 and is circulated inside the electrode 20 to thereby adjust the temperature of the electrode 20. Alternatively, a heating element, such as, e.g., a heater, may be used for the adjusting portion 31 and the heating element may be controlled by the setting portion 32 to adjust the temperature of the electrode 20 to the predetermined temperature.

By the film forming apparatus 1, for example, a thin film having a SiO_{X}C_{Y}:H structure obtained by plasma-polymerizing a material gas 510 containing hexamethyldisiloxane (HMDSO:O [Si(CH₃)₃]₂) and oxygen (O₂) can be formed as a barrier film on a workpiece 100 which is a resin material. At this time, when a metal material, such as, e.g., copper (Cu), is used as the material of the electrode 20, the difference in coefficient of thermal expansion between the barrier film formed on the workpiece 100 and the electrode 20 is large. Therefore, when the electrode 20 is deformed due to the temperature changes between the film forming process and other processes, the film forming material is separated from the electrode 20 due to the difference in the coefficient of thermal expansion between the electrode 20 and the film forming material deposited on the electrode 20.

However, in the film forming apparatus 1, the temperature of the electrode 20 is adjusted by the temperature adjustment device 30 so that the temperature of the electrode 20 is kept substantially constant from when the workpiece 100 is stored in the chamber 10 until when the workpiece is carried out of the chamber 10 after the film forming process. Therefore, the electrode 20 is not deformed, which suppresses separation of the film forming material from the electrode 20. Keeping the temperature of the electrode 20 substantially constant means that the electrode 20 is maintained at a temperature at which the electrode 20 is deformed only to the extent that the film forming material does not separate from the electrode 20, preferably the temperature of the electrode 20 is kept perfectly constant so that the electrode 20 does not deform at all.

The temperature of the electrode 20 can be arbitrarily set. For example, the temperature of the electrode 20 when the chamber 10 is opened to the atmosphere is adjusted to substantially the same temperature as the temperature of the electrode 20 in the film forming process so as to suppress the temperature drop of the electrode 20 due to the heat dissipation when the chamber 10 is opened to the atmosphere. Alternatively, the temperature of the electrode 20 may be adjusted according to the internal temperature of the chamber 10 when the film forming rate is high. In particular, it is preferable to adjust the temperature of the electrode 20 to a temperature at which the film forming rate is high and a film having a desired film quality is formed satisfactorily on the workpiece 100.

For example, as described below, the temperature of the electrode 20 is set according to the temperature of the workpiece 100 at the time of the film forming process. In the case where the workpiece 100 is made of resin, it is sometimes preferable to set the temperature of the workpiece 100 to be higher than the room temperature for film formation. For example, in the case of forming a film using an HMDSO, when the temperature of the workpiece 100 is 60° C. to 80° C., the film is satisfactorily deposited on the workpiece 100. When the workpiece 100 set at the predetermined temperature is stored in the chamber 10 as described above, the temperature of the electrode 20 is also set according to the temperature of the workpiece 100. With this, the temperature changes of the workpiece 100 can be suppressed. Therefore, the temperature of the electrode 20 is set to 60° C. to 80° C. by the temperature adjustment device 30.

Note that the temperature of the electrode 20 may be set to the temperature at which the chamber 10 is opened to the atmosphere by the temperature adjustment device 30. When the temperature of the electrode 20 during the film forming process is higher than the temperature of the electrode 20 when the chamber is in a state in which it is opened to the atmosphere, the temperature of the electrode 20 during the film forming process is lowered by using, for example, a Peltier element or the like as the adjusting portion 31.

However, by raising the temperature of the electrode 20, the moisture that adheres to the inner wall surface of the chamber 10 or the like when opening to the atmosphere can be reduced by the baking effect. With this, it is possible to suppress an increase in the time for exhausting the inside of the chamber 10. Therefore, the temperature of the electrode 20 is preferably higher than the room temperature. For this reason, the temperature of the electrode 20 is adjusted to be kept constant at a temperature higher than the temperature of the electrode 20 when the chamber 10 is opened to the atmosphere. For example, the temperature of the electrode 20 may be adjusted by the temperature adjustment device 30 so that the temperature of the electrode 20 becomes constant at the temperature in the film forming process in which the temperature of the electrode 20 is highest.

Temperature changes of the electrode 20 occur due to reasons other than the temperature changes between the temperature of the electrode 20 raised in the film forming process and the temperature of the electrode 20 dropped when the chamber 10 is opened to the atmosphere. For example, when the power supplied to the electrode 20 changes, the temperature of the electrode 20 changes. When the film forming time is long or when the film forming process is continuously performed while exchanging workpieces 100, the temperature of the electrode 20 gradually rises. In this way, when the temperature of the electrode 20 is not adjusted, temperature changes of the electrode 20 occur for each film forming process due to various factors.

On the other hand, in the film forming apparatus 1 according to the first embodiment of the present invention, the temperature of the electrode 20 is adjusted to be kept constant in a series of film forming processes including the film forming process. Therefore, separation of the film forming material from the electrode 20 due to the temperature changes of the electrode 20 is suppressed. As a result, according to the film forming apparatus 1, it is possible to prevent occurrence of problems, such as, e.g., adhering of the film forming material to the workpiece 100, deterioration of the film quality, and causing of uneven film thicknesses.

### (Second Embodiment)

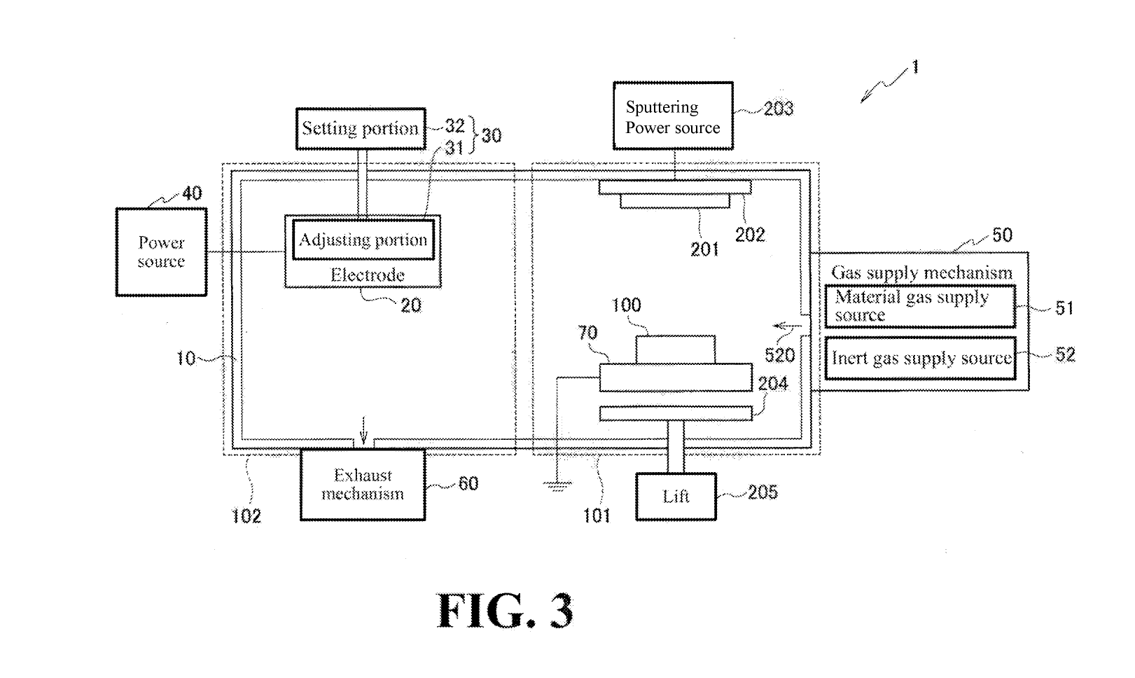

As shown in FIG. 3, the film forming apparatus 1 according to a second embodiment of the present invention is different from the film forming apparatus 1 shown in FIG. 1 in that a plurality of processing regions in which processes for a workpiece 100 are performed respectively is set in the chamber 10. Other configurations are the same as those in the first embodiment.

FIG. 3 shows an example in which a first processing region 101 and a second processing region 102 as a plurality of processing regions are set in the chamber 10. The workpiece holder 70 moves the workpiece 100 in the chamber 10 from the first processing region 101 to the second processing region 102 and vise versa.

The film forming apparatus 1 shown in FIG. 3 is an example in which the first processing region 101 is a sputtering processing region for forming a film on the workpiece 100 by a sputtering method and the second processing region 102 is a plasma CVD processing region for forming a film on the workpiece 100 by a plasma CVD method. In the first processing region 101, the target 201 is mounted on the target electrode 202. The target electrode 202 is connected to a sputtering power source 203 configured to supply high frequency (RF) power or direct current (DC) power to the target electrode. The configuration of the second processing region 102 is similar to that of the film forming apparatus 1 shown in FIG. 1.

Hereinafter, a case in which the processing in the sputtering processing region and the processing in the plasma CVD processing region are performed continuously will be described.

First, while adjusting the temperature of the electrode 20 to a predetermined temperature by the temperature adjustment device 30, the workpiece 100 is stored in the chamber 10, and the workpiece 100 is arranged in the first processing region 101 as shown in FIG. 3. An inert gas 520, such as, e.g., argon (Ar) gas, is introduced into the chamber 10 from the inert gas supply source 52 of the gas supply mechanism 50. Power is supplied from the sputtering power source 203 to the target electrode 202 to discharge the inert gas 520 to form plasma in the gas phase near the surface of the target 201. Positive ions of the inert gas 520 accelerated in the plasma collide with the surface of the target 201, and target atoms are released by sputtering. The atoms released from the surface of the target 201 are adhered/deposited on the surface of the workpiece 100 to form a thin film.

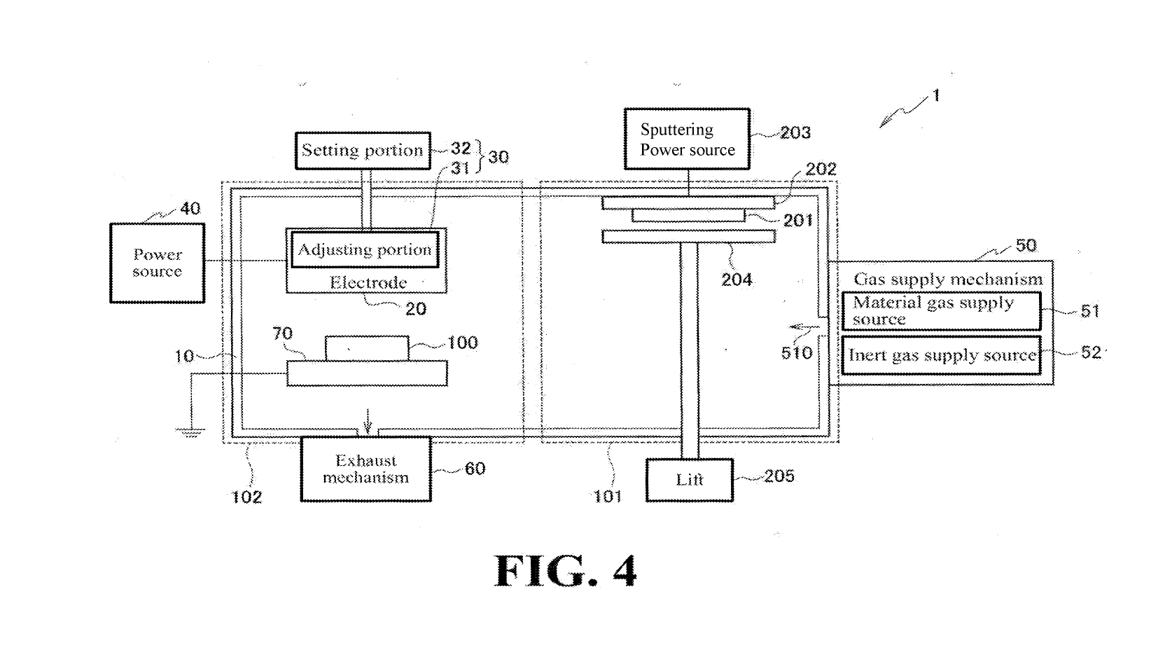

After completion of the sputtering process in the first processing region 101, as shown in FIG. 4, the workpiece 100 mounted on the workpiece holder 70 is moved from the first processing region 101 to the second processing region 102. Thereafter, in the second processing region 102, a film forming process by a plasma CVD method is performed for the workpiece 100 while adjusting the temperature of the electrode 20 to a predetermined temperature by the film forming method described with reference to FIG. 2. That is, a material gas 510 is introduced from the material gas supply source 51 of the gas supply mechanism 50 into the chamber 10 vacuumed by the exhaust mechanism 60. The material gas 510 is plasmatized in the chamber 10, so that a thin film is formed on the surface of the workpiece 100. Thereafter, the processed workpiece 100 is carried out of the chamber 10.

The temperature of the electrode 20 is adjusted by the temperature adjustment device 30 so that the temperature of the electrode 20 is kept constant during the film forming processes described above.

In the first processing region 101, a shutter 204 that moves in the vertical direction within the chamber 10 by a lift 205 is disposed. During the film forming process in the second processing region 102, the surface of the target 201 is protected by the raised shutter 204 as shown in FIG. 4. Also, while the chamber 10 is opened to the atmosphere when, e.g., exchanging workpieces 100, the surface of the target 201 is protected by the shutter 204. On the other hand, during the sputtering process, the shutter 204 is lowered as shown in FIG. 3.

As described above, according to the film forming apparatus 1 according to the second embodiment of the present invention, the process in the first processing region 101 and the process in the second processing region 102 can be performed in a continuous vacuumed manner. Therefore, it is possible to shorten the total process time as compared with the case of vacuuming the inside of the chamber for each process. Further, since the workpiece 100 is not exposed to the atmosphere, for example, it is possible to prevent deterioration of the film formed on the workpiece 100 and adherence of impurities to the film.

Furthermore, also in the film forming apparatus 1 according to the second embodiment, in the same manner as in the first embodiment, the temperature of the electrode 20 is adjusted by the temperature adjustment device 30 so that the temperature of the electrode 20 is kept constant in the film forming process by the plasma CVD method and in other processes other than the film forming process. Therefore, deformation of the electrode 20 due to temperature changes is suppressed, which in turn suppresses separation of the film forming material from the electrode 20 due to a difference in coefficient of thermal expansion between the electrode 20 and the film forming material. As a result, also in the film forming apparatus 1 according to the second embodiment, problems, such as, e.g., adherence of the film forming material separated from the electrode 20 to the workpiece 100, can be prevented. The others are substantially the same as those of the first embodiment, and redundant descriptions are omitted.

The order of process in the first processing region 101 and the process in the second processing region is arbitrary. For example, after performing a process in the first processing region 101 as described above, a process may be performed in the second processing region 102. Alternatively, after performing a process in the second processing region 102, a process may be performed in the first processing region 101.

The film forming apparatus 1 shown in FIG. 3 can be used for decorating injection molded plastic products and the like. For example, it is suitable for forming an aluminum film, a stainless steel (SUS) film, a titanium film, or the like in order to give a metal texture to automotive parts, such as, e.g., doorknobs and instruments. It can also be used for decorating, e.g., household appliances, toys, cosmetic containers, and dials of timepieces.

For example, after forming a first film (for example, an aluminum film or the like) which is easily oxidized on a workpiece 100 by a sputtering method, a second film as a protective film to prevent oxidation of the first film is formed so as to cover the first film by a plasma CVD method. For example, the film forming method can be effectively applied to the case of forming an aluminum film on the surface of a resin part in manufacturing a reflector of an automobile head lamp or the like,

### (Other Embodiments)

As described above, the present invention has been described in accordance with the embodiments, but it should not be understood that the description and drawings constituting a part of this disclosure limit the present invention. From this disclosure, various alternative embodiments, examples, and operational techniques will be apparent to those skilled in the art.

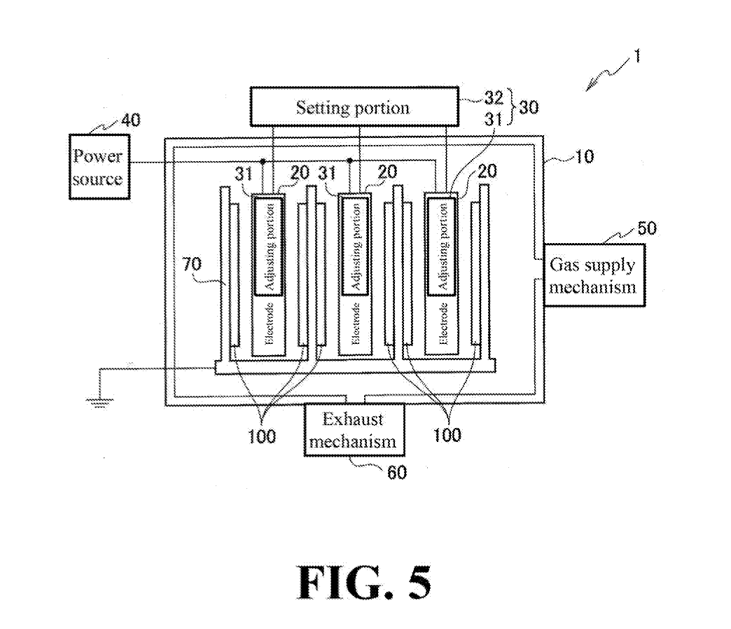

In the above description, an example is shown in which the workpiece 100 is horizontally mounted on the workpiece holder 70. However, for example, as shown in FIG. 5, the present invention may be applied to a film forming apparatus 1 in which workpieces 100 are vertically mounted on a boat type workpiece holder 70. In the film forming apparatus 1 shown in FIG. 5, the electrodes 20 face the workpieces 100 and extend in the vertical direction.

Although the case in which the film forming apparatus 1 is a plasma CVD apparatus has been described by way of example, even in a film forming apparatus using another film forming method, the present invention can be applied to a film forming apparatus having an electrode arranged in a chamber. For example, by setting the temperature of the target electrode of the sputtering apparatus to be kept constant by the temperature adjustment device 30, detachment of the film forming material from the target electrode can be suppressed.

As will be apparent from above, it goes without saying that the present invention can include various embodiments not described here.

1. A film forming apparatus for forming a film on a workpiece, comprising:
a chamber configured to store the workpiece;
an electrode to which power is supplied to form a film on the workpiece, the electrode being disposed in the chamber; and
a temperature adjustment device,
wherein the temperature adjustment device is configured to adjust a temperature of the electrode so that the temperature of the electrode is kept substantially constant in a film forming process for forming the film on the workpiece and in processes other than the film forming process during a series of film forming processes for forming the film on the workpiece to prevent separation of a film forming material deposited on the electrode from the electrode.

2. The film forming apparatus as recited in claim 1,
wherein the temperature adjustment device is configured to adjust the temperature of the electrode so that the temperature of the electrode when the chamber is opened to the atmosphere becomes substantially the same as a temperature of the electrode during the film forming process to suppress a temperature drop due to heat release when the chamber is opened to the atmosphere.

3. The film forming apparatus as recited in claim 1,
wherein the series of film forming processes to form the film on the workpiece is each process from a process for storing the workpiece in the chamber to a process for carrying out the workpiece from the chamber via the film forming process.

4. The film forming apparatus as recited in claim 1, further comprising:
a power source configured to supply the power to the electrode; and
a gas supply mechanism configured to supply a material gas into the chamber,
wherein the power source supplies the power to the electrode to form plasma of the material gas, so that the plasma is exposed to the workpiece to form a film containing a raw material contained in the material gas as a main component.

5. A film forming method including a series of film forming processes comprising:
storing a workpiece as a film forming process object in a chamber;
supplying predetermined power to an electrode disposed in the chamber to form a film on the workpiece; and
exposing the chamber to the atmosphere after forming the film on the workpiece,
wherein a temperature of the electrode is adjusted such that a temperature of the electrode is kept substantially constant in a film forming process for forming the film on the workpiece and in processes other than the film forming process to prevent separation of the film forming material deposited on the electrode.
